(19) United States
(12) Patent Application Publication
(10) Pub. No.: US 2013/0164936 A1
(43) Pub. Date: Jun. 27, 2013

(54) FILM DEPOSITION METHOD

(71) Applicant: Tokyo Electron Limited, Tokyo (JP)

(72) Inventors: Kentaro OSHIMO, Iwate (JP); Masato Koakutsu, Iwate (JP)

(73) Assignee: Tokyo Electron Limited, Tokyo (JP)

(21) Appl. No.: 13/726,728

(22) Filed: Dec. 26, 2012

(30) Foreign Application Priority Data
Dec. 27, 2011 (JP) 2011-285849

(51) Int. Cl. H01L 49/02

(52) U.S. Cl. CPC H01L 28/60
USPC 438/680

(57) ABSTRACT

A film deposition method includes a film depositing step of depositing titanium nitride on a substrate mounted on a substrate mounting portion of a turntable, which is rotatably provided in a vacuum chamber, by alternately exposing the substrate to a titanium containing gas and a nitrogen containing gas which is capable of reacting with the titanium containing gas while rotating the turntable; and an exposing step of exposing the substrate on which the titanium nitride is deposited to the nitrogen containing gas, the film depositing step and the exposing step being continuously repeated to deposit the titanium nitride of a desired thickness.

### CROSS-REFERENCE TO RELATED APPLICATION

The present application is based on Japanese Priority Application No. 2011-285849 filed on Dec. 27, 2011, the entire contents of which are hereby incorporated herein by reference.

### BACKGROUND OF THE INVENTION

1. Field of the Invention

The present invention relates to a film deposition method.

2. Description of the Related Art

In accordance with high integration of a semiconductor memory, a capacitor using a high dielectric material such as metallic oxide as a dielectric layer has been widely used. Electrodes of such a capacitor are made of titanium nitride (TiN), for example, with a relatively large work function.

The TiN electrode is formed by forming a TiN film on a high dielectric film by chemical vapor deposition (CVD) using titanium chloride (TiCl₄) and ammonia (NH₃) as source gasses, for example, and patterning the TiN film as disclosed in Patent Document 1, for example.

Here, in order to reduce a leakage current of the capacitor, the TiN film is formed at a deposition temperature lower than or equal to 400° C. However, there is a problem in that the resistance of the formed TiN film becomes high when the deposition temperature is low, for example about 300° C.

### [Patent Document]

### [Patent Document 1] Japanese Patent Publication No. 4,583,764

### SUMMARY OF THE INVENTION

The present invention is made in light of the above problems, and provides a film deposition method capable of lowering the resistance of TiN.

According to an embodiment, there is provided a film deposition method including a film depositing step of depositing titanium nitride on a substrate mounted on a substrate mounting portion of a turntable, which is rotatably provided in a vacuum chamber, by alternately exposing the substrate to a titanium containing gas and a nitrogen containing gas which is capable of reacting with the titanium containing gas while rotating the turntable; and an exposing step of exposing the substrate on which the titanium nitride is deposited to the nitrogen containing gas, the film depositing step and the exposing step being continuously repeated to deposit the titanium nitride of a desired thickness.

Note that also arbitrary combinations of the above-described constituents, and any exchanges of expressions in the present invention, made among methods, devices, systems and so forth, are valid as embodiments of the present invention.

### BRIEF DESCRIPTION OF THE DRAWINGS

Other objects, features and advantages of the present invention will become more apparent from the following detailed description when read in conjunction with the accompanying drawings.

FIG. 1 is a cross-sectional view of an example of a film deposition apparatus of an embodiment;

FIG. 2 is a perspective view showing an inside structure of a vacuum chamber of the film deposition apparatus shown in FIG. 1;

FIG. 3 is a schematic top view showing an example of the vacuum chamber of the film deposition apparatus shown in FIG. 1;

FIG. 4 is a partial cross-sectional view of an example of the film deposition apparatus shown in FIG. 1;

FIG. 5 is a partial cross-sectional view of an example of the film deposition apparatus shown in FIG. 1;

FIG. 6 is a flowchart showing a film deposition method of the embodiment;

FIG. 7 is a graph showing a result of an example;

FIG. 8 is a graph showing a result of an example;

FIGS. 9A and 9B are graphs showing a result of an example;

FIG. 10 is a sequence diagram showing gasses to which a substrate is exposed in the film deposition method of the embodiment; and

FIG. 11 is a schematic view showing an example of a process recipe of a TiN film of the embodiment.

### DETAILED DESCRIPTION OF THE PREFERRED EMBODIMENTS

The invention will be described herein with reference to illustrative embodiments. Those skilled in the art will recognize that many alternative embodiments can be accomplished using the teachings of the present invention and that the invention is not limited to the embodiments illustrated for explanatory purposes.

It is to be noted that, in the explanation of the drawings, the same components are given the same reference numerals, and explanations are not repeated. Further, drawings are not intended to show relative ratio of a component or components.

### (Film Deposition Apparatus)

First, a film deposition apparatus for performing a film deposition method of the embodiment is explained.

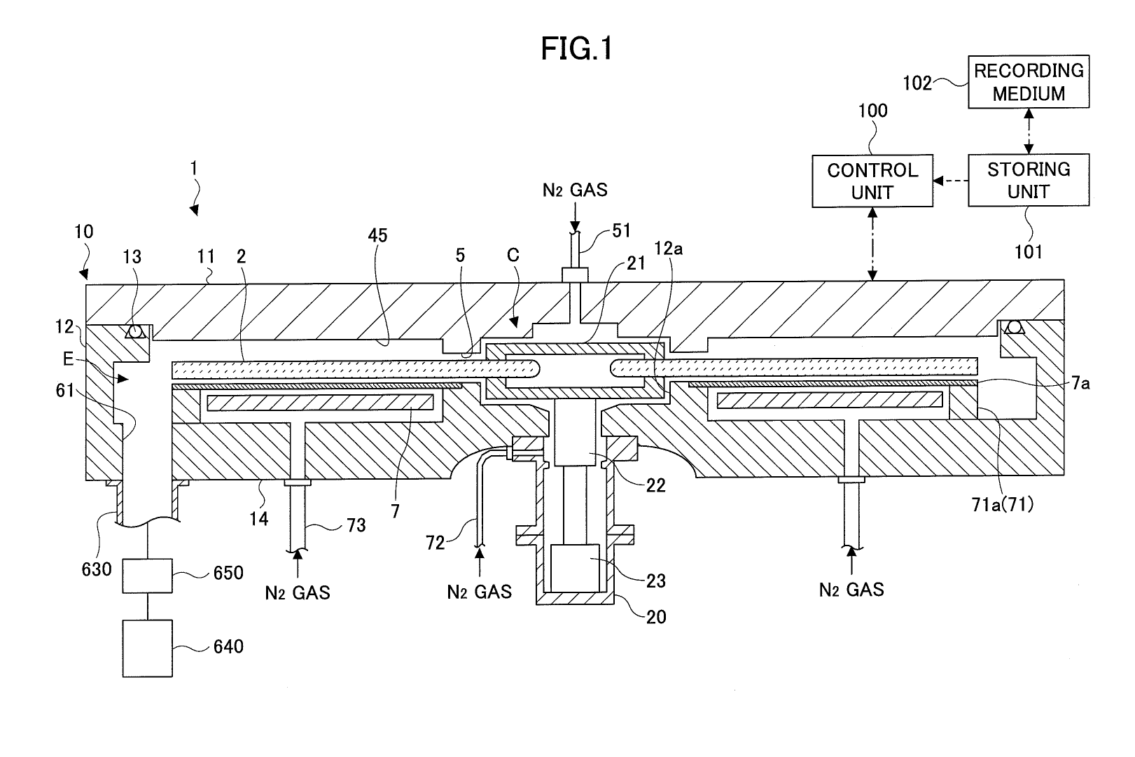

FIG. 1 is a cross-sectional view of an example of a film deposition apparatus 1 of the embodiment.

The film deposition apparatus 1 includes a vacuum chamber 10, a turntable 2, a heater unit 7, a case body 20, a core unit 21, a rotary shaft 22, and a driving unit 23. The vacuum chamber 10 has a substantially flat circular shape. The vacuum chamber 10 includes a chamber body 12 having a cylindrical shape with a bottom surface, and a ceiling plate 11 placed on the upper surface of the chamber body 12. The ceiling plate 11 is detachably placed on the chamber body 12 via a sealing member 13 (FIG. 1) such as an O-ring in an airtight manner.

The turntable 2 is provided in the vacuum chamber 10 and has a center of rotation at the center of the vacuum chamber 10. The turntable 2 is attached to the cylindrical shaped core unit 21 at its center portion. The core unit 21 is fixed to the upper end of the rotary shaft 22 which is extending in the vertical direction. The rotary shaft 22 is provided to penetrate the bottom portion 14 of the vacuum chamber 10 and the lower end of which is attached to the driving unit 23 that rotates the rotary shaft 22 (FIG. 1) around a vertical direction. The rotary shaft 22 and the driving unit 23 are housed in the tubular case body 20 whose upper surface is open. The case body 20 is attached to a lower surface of the bottom portion 14 of the vacuum chamber 10 via a flange portion provided at its upper surface in an airtight manner so that inner atmosphere of the case body 20 is isolated from outside atmosphere.

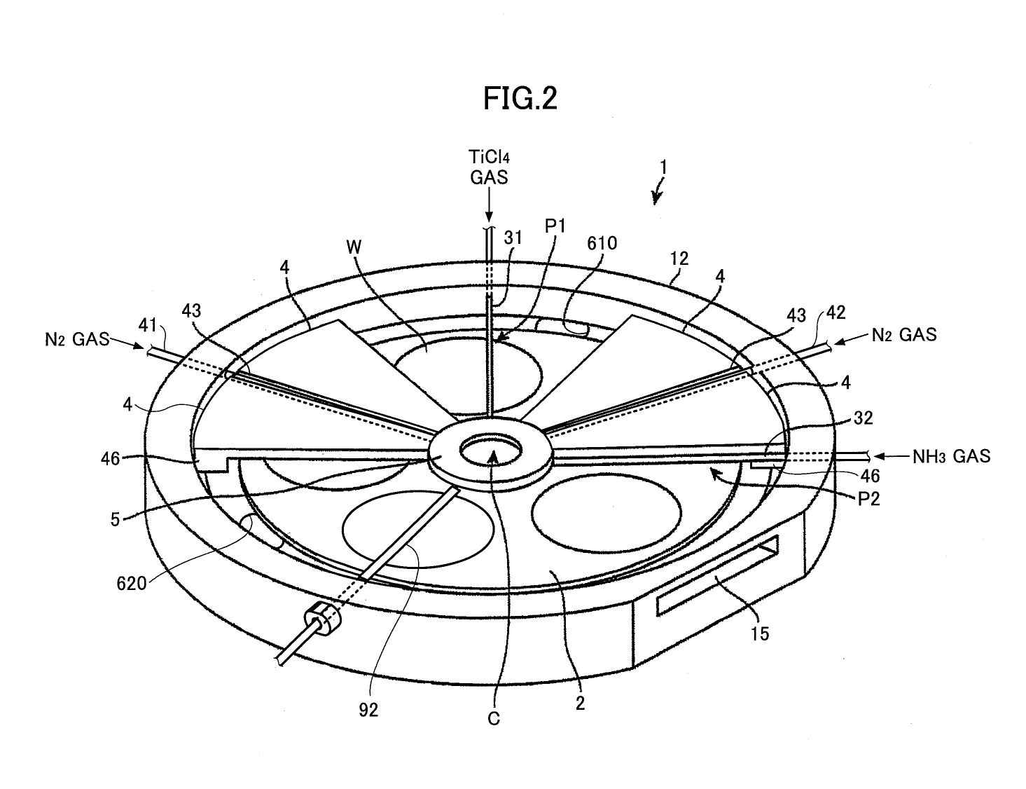

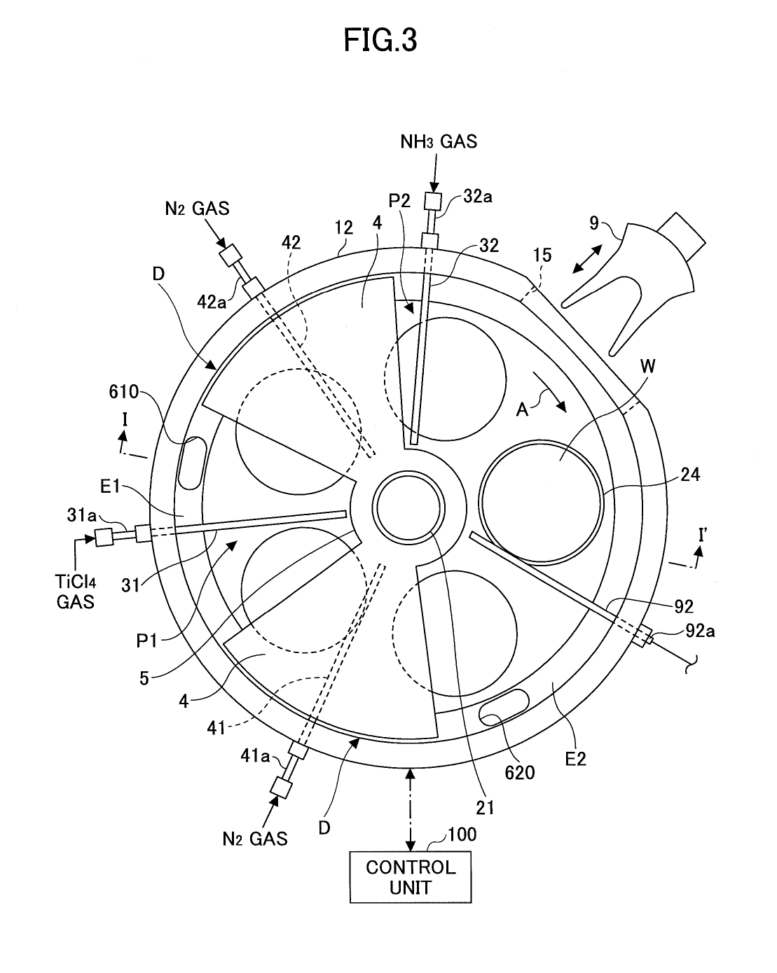

FIG. 2 and FIG. 3 are views showing an inside structure of the vacuum chamber 10. The ceiling plate 11 is not shown in FIG. 2 and FIG. 3 for an explanatory purpose.

As shown in FIG. 2 and FIG. 3, plural (five in this case) circular concave portions 24 are provided at a front surface of the turntable 2 along a rotating direction (circumferential direction) shown by an arrow A for placing plural semiconductor wafers (which will be simply referred to as “wafers” hereinafter) W, respectively. Here, an example where the wafer W is shown to be placed in one of the concave portions 24 in FIG. 3 for an explanatory purpose.

Each of the concave portions 24 is formed to have a slightly larger (for example, 4 mm larger) diameter than that (for example, 300 mm) of the wafer W, and a depth substantially equal to the thickness of the wafer W. Thus, when the wafer W is mounted in the respective concave portion 24, the surface of the wafer W and the surface of the turntable 2 (where the wafer W is not mounted) becomes almost the same height.

As will be explained later, each of the concave portions 24 are provided with three, for example, through holes, through which lift pins for supporting a back surface of the respective wafer W and lifting the wafer W penetrate.

A reaction gas nozzle 31, a reaction gas nozzle 32, and separation gas nozzles 41 and 42, which are made of quartz, for example, are provided above the turntable 2. For the example shown in FIG. 3, the separation gas nozzle 41, the reaction gas nozzle 31, the separation gas nozzle 42, and the reaction gas nozzle 32 are aligned in this order from a transfer port 15 (which will be explained later) in a clockwise direction (the rotation direction of the turntable 2) with a space therebetween in a circumferential direction of the vacuum chamber 10. Gas introduction ports 31a, 32a, 41a, and 42a (FIG. 3) which are base portions of the nozzles 31, 32, 41, and 42, respectively, are fixed to an outer periphery wall of the fixing chamber body 12 so that these nozzles 31, 32, 41, and 42 are introduced into the vacuum chamber 10 from the outer periphery wall of the vacuum chamber 10 to extend in parallel with respect to a surface of the turntable 2 along a radius direction.

In this embodiment, as will be explained later, a TiN film is formed on the wafer W. Thus, in this embodiment, the reaction gas nozzle 31 is connected to a titanium chloride (TiCl₄) gas supplying source (not shown in the drawings) via a pipe, a flow-controller and the like, not shown in the drawings. The reaction gas nozzle 32 is connected to an ammonia supplying source (not shown in the drawings) via a pipe, a flow-controller and the like, not shown in the drawings. The separation gas nozzles 41 and 42 are connected to separation gas supplying sources (not shown in the drawings) via open valves and flow-controllers (neither is shown in the drawings), respectively. The separation gas may be a noble gas such as Ar or He, an inactive gas such as nitrogen gas or the like. In this embodiment, N₂ gas is used.

The reaction gas nozzles 31 and 32 are provided with plural gas discharge holes 33 (see

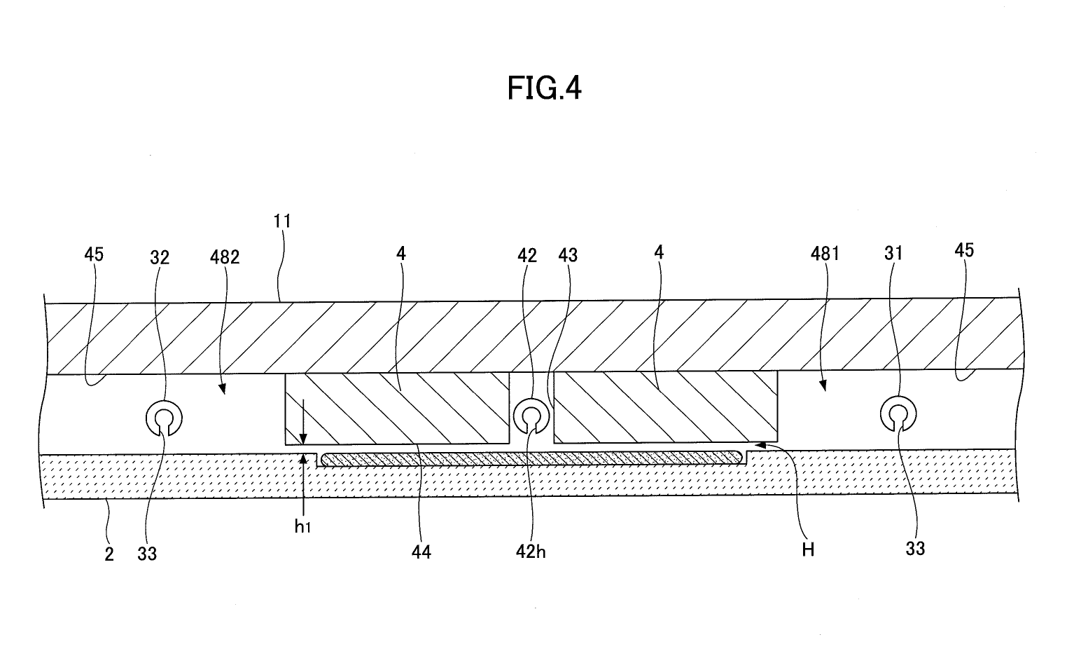

FIG. 4) which are facing downward to the turntable 2 along the longitudinal directions of the reaction gas nozzles 31 and 32 with a 10 mm interval, respectively, for example. An area below the reaction gas nozzle 31 is a first process area P1 in which the TiCl₄ gas is adsorbed onto the wafers W. An area below the reaction gas nozzle 32 is a second process area P2 in which the TiCl₄ gas adsorbed onto the wafers W at the first process area P1 is nitrided.

Referring to FIG. 2 and FIG. 3, the ceiling plate 11 is provided with two protruding portions 4 protruding in the vacuum chamber 10. Each of the protruding portions 4 has substantially a sector top view shape where the apex is removed in an arc shape. For each of the protruding portions 4, the inner arc shaped portion is connected to an inner protruding portion 5 (which will be explained later with reference to FIG. 1 to FIG. 3) and the outer arc shaped portion is formed to extend along an inner peripheral surface of the chamber body 12 of the vacuum chamber 10. As will be explained later, the protruding portions are attached at a lower surface of the ceiling plate 11 to protrude toward the turntable 2 to form separation areas D with the corresponding separation gas nozzles 41 and 42.

FIG. 4 shows a cross-section of the vacuum chamber 10 along a concentric circle of the turntable 2 from the reaction gas nozzle 31 to the reaction gas nozzle 32. As shown in FIG. 4, the protruding portion 4 is fixed to a lower surface of the ceiling plate 11. Thus, there are provided a flat low ceiling surface 44 (first ceiling surface) formed below the respective protruding portion 4 and flat higher ceiling surfaces 45 (second ceiling surface) which are higher than the low ceiling surface 44 and formed at outboard sides of the respective low ceiling surface 44 in the circumferential direction.

Further, as shown in the drawings, the protruding portion 4 is provided with a groove portion 43 at a center in the circumferential direction. The groove portion 43 is formed to extend in the radius direction of the turntable 2. The separation gas nozzle 42 is positioned within the groove portion 43. Although not shown in FIG. 4, the separation gas nozzle 41 is also positioned within a groove portion provided in the other protruding portion 4. The reaction gas nozzles 31 and 32 are provided in spaces below the high ceiling surfaces 45, respectively. The reaction gas nozzles 31 and 32 are provided in the vicinity of the wafers W apart from the high ceiling surfaces 45, respectively. Here, for an explanatory purpose, a space below the high ceiling surface 45 where the reaction gas nozzle 31 is provided is referred to as “481” and a space below the high ceiling surface 45 where the reaction gas nozzle 32 is provided is referred to as “482” as shown in FIG. 4.

The separation gas nozzle 42 (or 41) is provided with plural gas discharge holes 42h formed along the longitudinal direction of the separation gas nozzle 42 (or 41) with a predetermined interval (10 mm, for example).

The low ceiling surface 44 provides a separation space H, which is a small space, with respect to the turntable 2. When the N₂ gas is provided from the separation gas nozzle 42, the N₂ gas flows toward the space 481 and the space 482 through the separation space H. At this time, as the volume of the separation space H is smaller than those of the spaces 481 and 482, the pressure in the separation space H can be made higher than those in the spaces 481 and 482 by the N₂ gas. It means that between the spaces 481 and 482, the separation space H provides a pressure barrier. Further, the N₂ gas flowing from the separation space H toward the spaces 481 and 482 functions as a counter flow against the TiCl₄ gas from the gas first process area P1 and the NH₃ gas from the second process area P2. Thus, the TiCl₄ gas from the first process area P1 and the NH₃ gas from the second process area P2 are separated by the separation space H. Therefore, mixing and reacting of the TiCl₄ gas with the NH₃ gas are prevented in the vacuum chamber 10.

The height h1 of the low ceiling surface 44 above an upper surface of the turntable 2 may be appropriately determined based on the pressure of the vacuum chamber 10 at a film deposition time, the rotational speed of the turntable 2, and a supplying amount (flow rate) of the separation gas (N₂ gas) in order to maintain the pressure in the separation space H higher than those in the spaces 481 and 482.

Referring to FIG. 1 to FIG. 3, the ceiling plate 11 is further provided with the inner protruding portion 5 at its lower surface to surround the outer periphery of the core unit 21 which fixes the turntable 2. The inner protruding portion 5 is continuously formed with the inner portion of the protruding portions 4 and a lower surface which is formed at the same height as those of the low ceiling surfaces 44, in this embodiment.

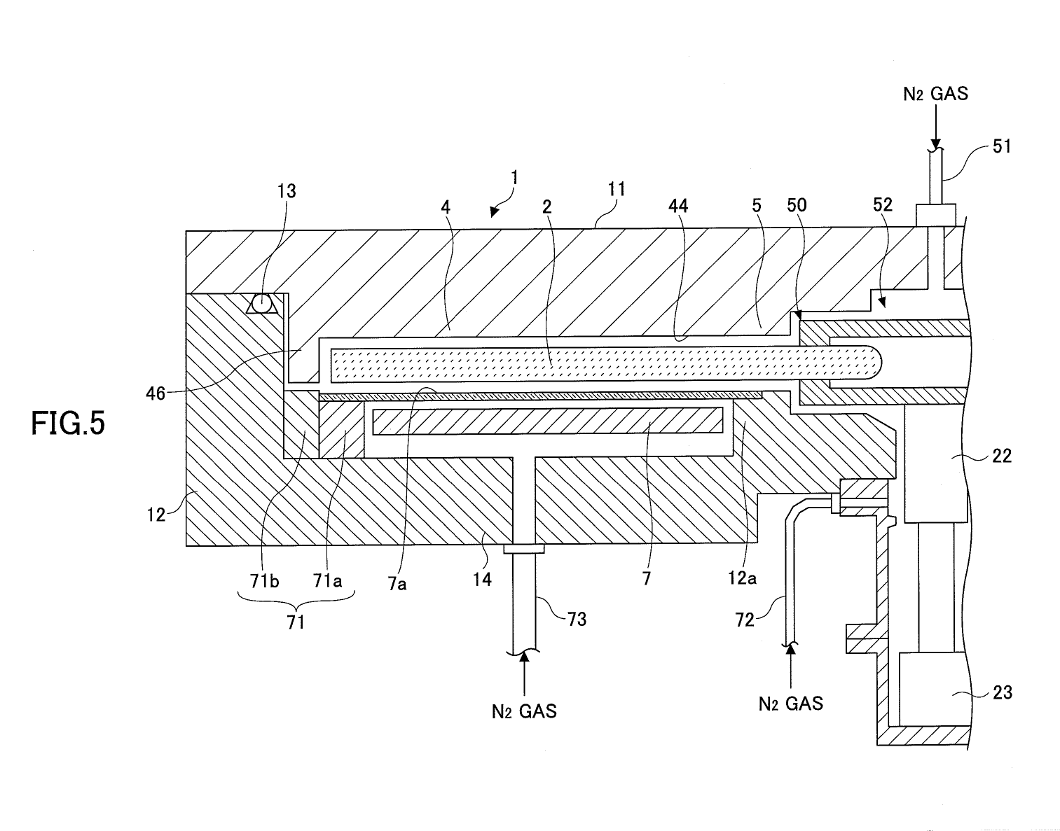

FIG. 1 is a cross-sectional view taken along an I-I′ line in FIG. 3, and showing an area where the ceiling surface 45 is provided. FIG. 5 is a partial cross-sectional view showing an area where the ceiling surface 44 is provided.

As shown in FIG. 5, the protruding portion 4 having a substantially sector top view shape is provided with an outer bending portion 46 at its outer peripheral end portion (at an outer peripheral end portion side of the vacuum chamber 10) which is bent to have an L-shape to face an outer end surface of the turntable 2. The outer bending portion 46 suppresses a flow of gas between the space 481 and the space 482 through the space between the turntable 2 and the inner peripheral surface of the chamber body 12. As described above, the protruding portions 4 are attached to the ceiling plate 11 and the ceiling plate 11 is detachably attached to the chamber body 12. Thus, there is a slight space between the outer periphery surface of the outer bending portion 46 and the chamber body 12. The space between the inner periphery surface of the outer bending portion 46 and an outer surface of the turntable 2, and the space between the outer periphery surface of the outer bending portion 46 and the chamber body 12 may be a size the same as the height h1 (see FIG. 4) of the low ceiling surface 44 with respect to the upper surface of the turntable 2, for example.

As shown in FIG. 5, the inside perimeter wall of the chamber body 12 is provided to extend in a vertical direction to be closer to the outer peripheral surface of the outer bending portion 46 at the separation area H. However, other than the separation area H, as shown in FIG. 1, for example, the inside perimeter wall of the chamber body 12 is formed to have a concave portion outside from a portion facing the outer end surface of the turntable 2 toward the bottom portion 14. Hereinafter, for an explanatory purpose, the concave portion, having a substantially rectangular cross-sectional view, is referred to as an “evacuation area”. Specifically, a part of the evacuation area which is in communication with the first process area P1 is referred to as a first evacuation area E1, and a part of the evacuation area which is in communication with the second process area P2 is referred to as a second evacuation area E2. As shown in FIG. 1 to FIG. 3, a first evacuation port 610 and a second evacuation port 620 are respectively provided at the bottom portions of the first evacuation area E1 and the second evacuation area E2. The first evacuation port 610 and the second evacuation port 620 are connected to vacuum pumps 640, which are vacuum evacuation units, via evacuation pipes 630, respectively, as shown in FIG. 1. The reference numeral 650 is a pressure regulator in FIG. 1.

The heater unit 7 is provided at a space between the turntable 2 and the bottom portion 14 of the vacuum chamber 10 as shown in FIG. 1 and FIG. 5. The wafers W mounted on the turntable 2 are heated by the heater unit 7 via the turntable 2 to be a temperature (450° C., for example) determined by a process recipe. A ring cover member 71 is provided at a lower portion side of the outer periphery of the turntable 2 in order to separate an atmosphere above the turntable 2 toward the evacuation areas E1 and E2 and an atmosphere where the heater unit 7 is provided so that the gasses are prevented from being introduced into the space below the turntable 2.

As shown in FIG. 5, the cover member 71 includes an inner member 71a which is provided to face the outer edge portion and the further outer portion of the turntable 2 from a lower side, and an outer member 71b which is provided between the inner member 71a and an inner wall surface of the chamber body 12. The outer member 71b is provided to face the outer bending portion 46, which is formed at an outer edge portion at lower side of each of the protruding portions 4. The inner member 71a is provided to surround the entirety of the heater unit 7 below the outer end portion (and at a slightly outer side of the outer end portion) of the turntable 2.

As shown in FIG. 1, the bottom portion 14 of the vacuum chamber 10 closer to the rotation center than the space where the heater unit 7 is positioned protrudes upward to be close to the core unit 21 to form a protruded portion 12a. There is provided a small space between the protruded portion 12a and the core unit 21. Further, there is provided a small space between an inner peripheral surface of the bottom portion 14 and the rotary shaft 22 to be in communication with the case body 20. A purge gas supplying pipe 72 which supplies N₂ gas as the purge gas to the small space for purging is provided in the case body 20. The bottom portion 14 of the vacuum chamber 10 is provided with plural purge gas supplying pipes 73 (only one of the purge gas supplying pipes 73 is shown in FIG. 5) which are provided with a predetermined angle interval in the circumferential direction below the heater unit 7 for purging the space where the heater unit 7 is provided. Further, a cover member 7a is provided between the heater unit 7 and the turntable 2 to prevent the gas from being introduced into the space where the heater unit 7 is provided. The cover member 7a is provided to extend from an inner peripheral wall (upper surface of the inner member 71a) of the outer member 71b to an upper end portion of the protruded portion 12a in the circumferential direction. The cover member 7a may be made of quartz, for example.

The film deposition apparatus 1 further includes a separation gas supplying pipe 51 which is connected to a center portion of the ceiling plate 11 of the vacuum chamber 10 and provided to supply N₂ gas as the separation gas to the space 52 between the ceiling plate 11 and the core unit 21. The separation gas supplied to the space 52 flows through a small space between the inner protruding portion 5 and the turntable 2 to flow along a front surface of the turntable 2 where the wafers W are to be mounted to be discharged from an outer periphery. The space 50 is kept at a pressure higher than those of the space 481 and the space 482 by the separation gas. Thus, the mixing of the TiCl₄ gas supplied to the first process area P1 and the NH₃ gas supplied to the second process area P2 by flowing through the center area C can be prevented by the space 50. It means that the space 50 (or the center area C) can function similarly as the separation space H (or the separation area D).

Further, as shown in FIG. 2 and FIG. 3, a transfer port 15 is provided at a side wall of the vacuum chamber 10 for allowing the wafers W, which are substrates, to pass between an external transfer arm 9 and the turntable 2. The transfer port 15 is opened and closed by a gate valve (not shown in the drawings). Further, lift pins, which penetrate the concave portion 24 to lift up the respective wafer W from a backside surface, and a lifting mechanism for the lift pins (neither is shown in the drawings) are provided at respective portions below the turntable 2. Thus, the respective wafer W is passed between the external transfer arm 9 and the concave portion 24 of the turntable 2, which is a mounting portion, at a place facing the transfer port 15.

As shown in FIG. 1, the film deposition apparatus 1 of the embodiment further includes a control unit 100 which controls the entirety of the film deposition apparatus 1 and a storing unit 101. The control unit 100 may be a computer. The storing unit 101 stores a program by which the film deposition apparatus 1 executes the film deposition method (as will be explained later) under control of the control unit 100. The program is formed to include steps capable of executing the film deposition method. The storing unit 101 may be a hard disk or the like, for example. The program stored in the storing unit 101 may be previously stored in a recording medium 102 such as a compact disk (CD), a magneto-optical disk, a memory card, a flexible disk, or the like to be installed in the storing unit 101 using a predetermined reading device.

### (Film Deposition Method)

In this embodiment, in order to form a TiN film with a desired thickness, a step of forming a TiN film with a thickness less than the desired thickness and a step of exposing to the nitrogen containing gas is repeated to form the TiN film with the desired thickness.

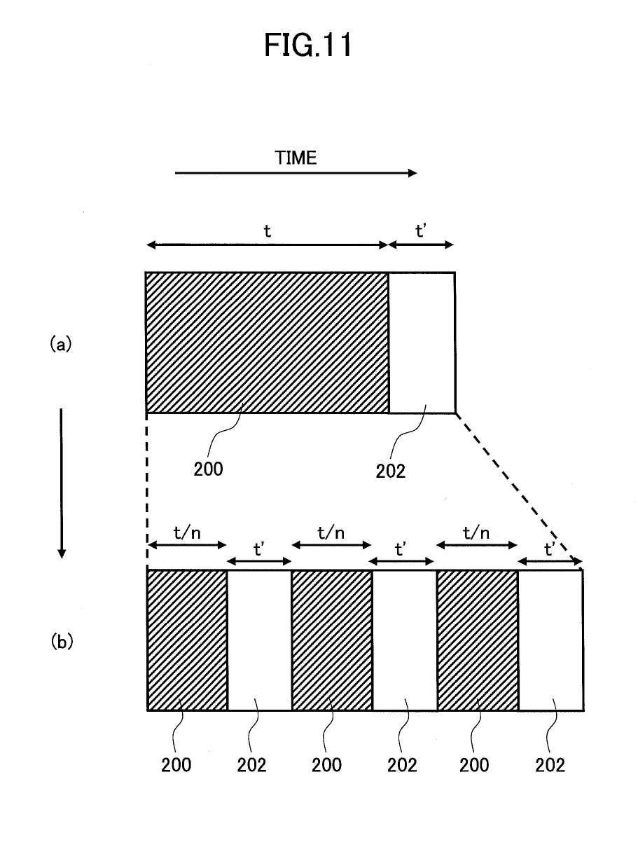

FIG. 11 is a schematic view showing an example of a process recipe for a TiN film of the embodiment.

In this embodiment, a step of forming a TiN film by supplying the TiCl₄ gas and the NH₃ gas while rotating the turntable 2 is referred to as a “film deposition step 200”, and a step of supplying the NH₃ gas while rotating the turntable 2 is referred to as an “NH₃ process step 202”.

In (a) of FIG. 11, an example where the NH₃ process step 202 is performed after a TiN film with a desired thickness “d” is formed in the film deposition step 200. Here, it is assumed that the period necessary for depositing the TiN film with the desired thickness “d” when the turntable 2 is rotated at a predetermined rotational speed “r” (revolutions/minute: rpm) is “t”, for example.

In this embodiment, as shown in (b) of FIG. 11, the film deposition step 200 for depositing the TiN film with the desired thickness “d” is divided by a predetermined number “n” and the NH₃ process step 202 is performed for each of the divided film deposition steps 200, different from the case shown in (a) where the NH₃ process step 202 is performed only after the TiN film with the desired thickness “d” is deposited. In other words, in order to deposit the TiN film with the desired thickness “d” while rotating the turntable 2 at the predetermined rotational speed “r” (revolutions/minute: rpm), the film deposition step 200 is performed for a period “t/n”, the NH₃ process step 202 is performed every time the film deposition step 200 is performed for the period “t/n”, and these steps are repeated for “n” times (where “n” is an integer more than or equal to 2).

In other words, in this embodiment, the TiN film with a desired thickness “d” is formed by repeating the film deposition step 200 in which the TiN film with the thickness “d/n” is deposited, and the NH₃ process step 202 for “n” times. The “n” is referred to as a cycle number, hereinafter.

Here, when the period of the NH₃ process step 202 in (a) is “t′”, the period of each of the NH₃ process steps 202 in (b) is also “t′”. However, the period of each of the NH₃ process steps 202 in (b) may be shorter than “t′”.

When the process shown in (b) of FIG. 11 is used, the cycle number may be determined such that the thickness of a deposited film is less than or equal to 10 nm, preferably, less than or equal to 3 nm, in each of the film deposition steps 200.

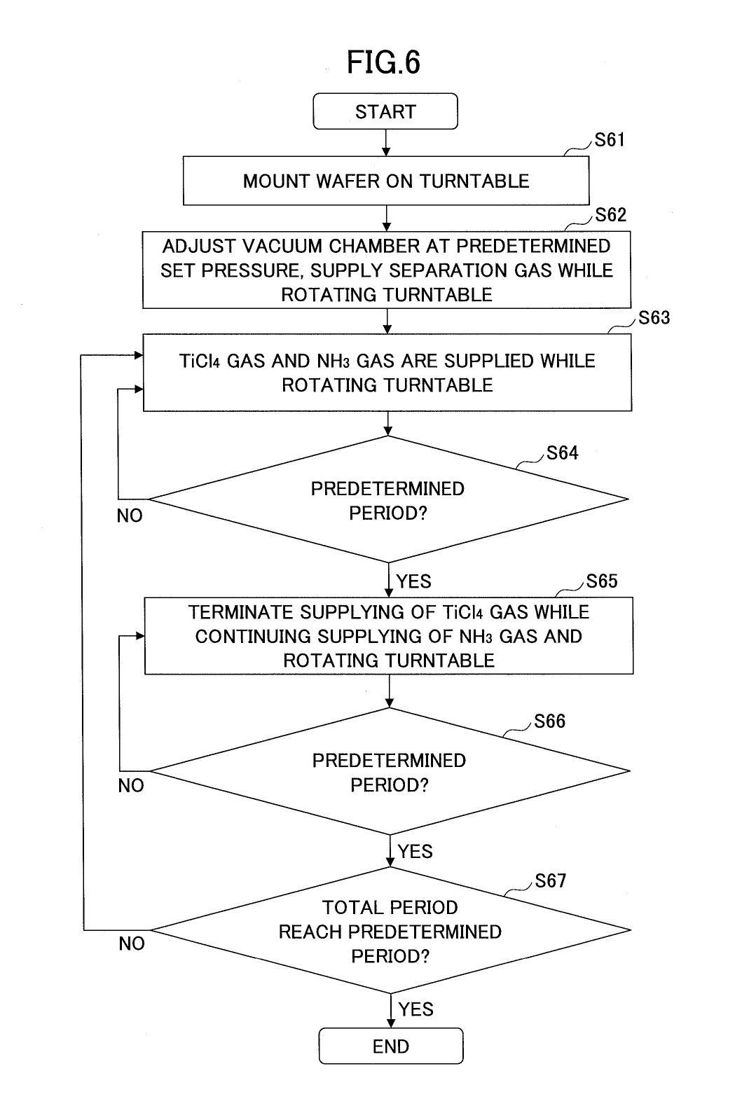

The film deposition method of the embodiment is explained with reference to FIG. 6. In the following, an example where the film deposition apparatus 1 is used is explained. FIG. 6 is a flowchart showing a film deposition method of the embodiment.

First, in step S61, the wafer W is mounted on the turntable 2. Specifically, the gate valve (which is not shown in the drawings) is opened, and the wafer W is passed to the concave portion 24 of the turntable 2 via the transfer port 15 (FIG. 3) by the transfer arm 9. This operation is performed by lifting the lift pins (not shown in the drawings) via through holes provided at a bottom surface of the concave portion 24 from the bottom portion side of the vacuum chamber 10 when the concave portion 24 stops at a position facing the transfer port 15. By repeating this operation while intermittently rotating the turntable 2, the wafers W are mounted within the concave portions 24, respectively.

Then, the gate valve is closed, and the vacuum chamber 10 is evacuated by the vacuum pump 640 to the minimum vacuum level. Then, in step S62, the N₂ gas is supplied from the separation gas nozzles 41 and 42 at a predetermined flow rate, respectively. Further, the N₂ gas is also discharged from the separation gas supplying pipe 51 and the purge gas supplying pipes 72 and 73 at a predetermined flow rate, respectively. With this, the vacuum chamber 10 is adjusted to a predetermined set pressure by the pressure regulator 650 (FIG. 1). Then, the wafers W are heated to 400° C., for example, by the heater unit 7 while rotating the turntable 2 in a clockwise direction at a rotational speed of 20 rpm, for example.

Thereafter, in step S63, the TiCl₄ gas is supplied from the reaction gas nozzle 31, while the NH₃ gas is supplied from the reaction gas nozzle 32 (FIG. 2 and FIG. 3). The wafer W passes through the first process area P1, the separation area D (separation space H), the second process area P2, and the separation area D (separation space H) in this order by the rotation of the turntable 2 (see FIG. 3). First, in the first process area P1, the TiCl₄ gas from the reaction gas nozzle 31 is adsorbed onto the wafer W. Then, when the wafer W reaches the second process area P2 after passing through the separation space H (separation area D), which has a N₂ gas atmosphere, the TiCl₄ gas adsorbed onto the wafer W reacts with the NH₃ gas from the reaction gas nozzle 32 so that the TiN film is deposited on the wafer W. At this time, NH₄Cl is generated as a by-product and is discharged into a gas phase to be evacuated with the separation gas and the like. Then, the wafer W reaches the separation area D (separation space H at N₂ gas atmosphere). These processes correspond to the film deposition step 200.

Meanwhile, whether supplying of the TiCl₄ gas from the reaction gas nozzle 31 and the NH₃ gas from the reaction gas nozzle 32 is performed for a predetermined period is determined (step S64). The predetermined period may be previously determined based on an experimental result or the like. The predetermined period becomes “t/n” for the case explained above with reference to FIG. 11, for example.

When the predetermined period has not passed yet (step S64: NO), the deposition of the TiN film (step S63) is continued, while when the predetermined period has already passed (YES of step S64), the process proceeds to the next step S65.

In step S65, supplying of the TiCl₄ gas from the reaction gas nozzle 31 is terminated while the rotation of the turntable 2 and supplying of the NH₃ gas from the reaction gas nozzle 32 are continued. With this, the wafer W is alternately exposed to the N₂ gas (separation gas) and the NH₃ gas. There is a possibility that unreacted TiCl₄ or chloride (Cl) generated by the decomposition of TiCl₄ exists in the deposited TiN film. The unreacted TiCl₄ reacts with the NH₃ gas to form TiN, and the remaining Cl reacts with the NH₃ gas to be NH₄Cl and eliminated from the deposited film. Thus, impurities within the deposited TiN film are reduced to improve the film quality of the TiN film so that the resistance is lowered. This process corresponds to the NH₃ process step 202.

Then, whether supplying of the NH₃ gas from the reaction gas nozzle 32 is performed for a predetermined period after starting step S65 is determined (step S66). The predetermined period may be previously determined based on an experimental result of the like. The predetermined period is “t′” for the case explained above with reference to FIG. 11.

When the predetermined period has not passed (step S66: NO), the process of step S65 is continued, and when he predetermined period has passed (step S66: YES), the process moves to the next step S67.

In step S67, whether the total period of step

S63 and step S65 has reached a predetermined period is determined. When the total period has not reached the predetermined period (step S67: NO), the process moves back to step S63 and TiN is further deposited. When the total period has reached the predetermined period (step S67: YES of), supplying of the NH₃ gas is terminated and the film deposition is finished. In step S67, whether to finish the film deposition may be determined based on whether the film deposition step 200 and the NH₃ process step 202 are performed for a predetermined number of times. At this time, the predetermined number of times is “n” for the case explained above with reference to FIG. 11.

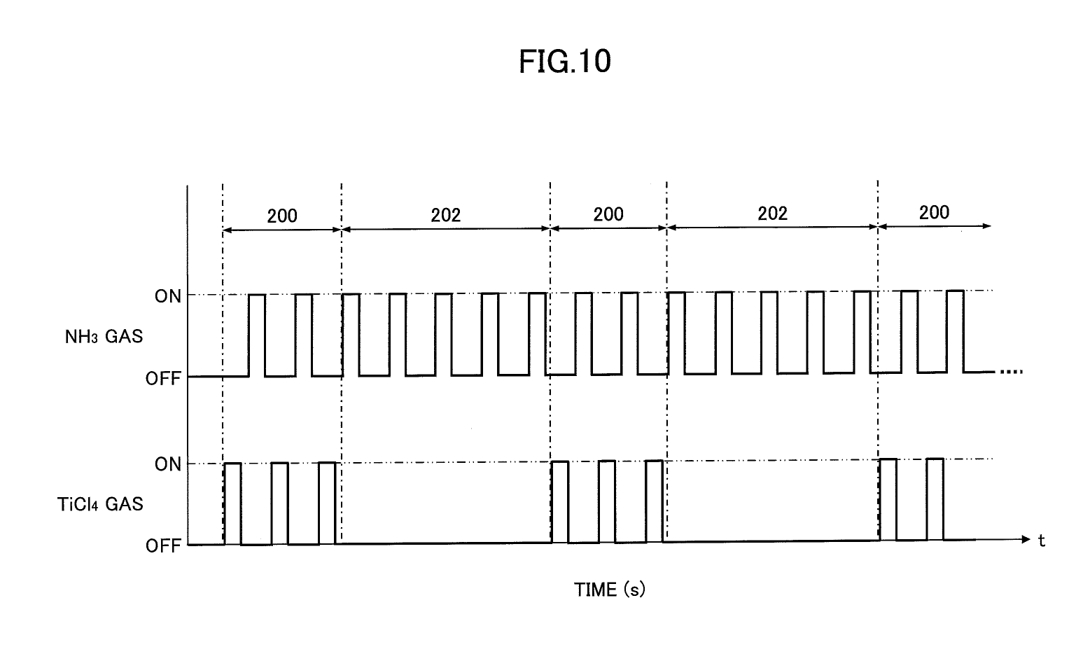

FIG. 10 is a timing chart for explaining the film deposition method of the embodiment.

Here, according to the film deposition method of the embodiment, the wafer W is exposed to each of the gasses as shown in FIG. 10. It means that the wafer W is alternately exposed to the TiCl₄ gas and the NH₃ gas in the film deposition step 200, and periodically exposed to the NH₃ gas in the NH₃ process step 202. The wafer W is exposed to the separation gas (N₂ gas) other than the periods of being exposed to one of the TiCl₄ gas and the NH₃ gas.

Examples are explained. The temperature of the wafer W is the same in the film deposition step and in the NH₃ process step.

### Example 1

First, relationships between the sheet resistance of the deposited TiN film and the rotational speed of the turntable 2 and the cycle number are examined. Here, the cycle number means a repeating number of cycles where one cycle is assumed as a combination of the film deposition step and the NH₃ process step. For example, when the cycle number is 4, the film deposition step and NH₃ process step are alternately repeated for four times, and when the cycle number is 10, the film deposition step and the NH₃ process step are alternately repeated for 10 times. Further, in this example, as the targeted thickness of the TiN film is set to be 10 nm, the film deposition step for each of the cycles becomes shorter in a case where the cycle number is 10 than in a case where the cycle number is 4. In other words, the larger the cycle number is, the shorter is the period of the film deposition step for each of the cycles.

The main conditions in this example are as follows.
the temperature of the turntable 2 (deposition temperature): 300° C.
the rotational speed of the turntable 2: 30 or 240 rpm
TiCl₄ gas flow rate: 150 sccm
NH₃ gas flow rate: 15000 sccm
the total separation gas flow rate from the separation gas nozzles 41 and 42: 10000 sccm
the targeted thickness of the TiN film: 10 nm

The deposited TiN film is evaluated by measuring the sheet resistance (the same in the following examples).

For a comparative example, a sample is obtained by only performing the film deposition step until a TiN film of the targeted thickness 10 nm is deposited on a wafer W and then exposing the TiN film to the NH₃ gas. Then, the sheet resistance is measured. For the relative example, the TiN films are deposited at deposition temperatures of 350° C., 400° C., and 500° C. in addition to 300° C. (the temperature of the wafer W when the TiN film is exposed to the NH₃ gas is the same as the deposition temperature for each case).

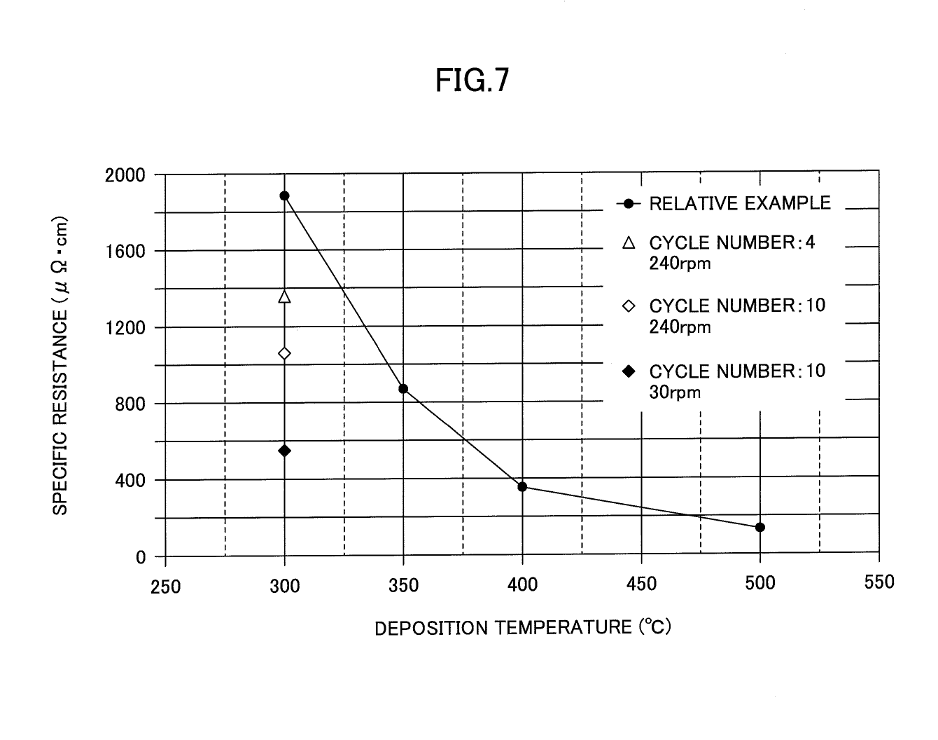

FIG. 7 is a graph showing a result of the example 1. The results of the comparative example are also shown in this graph. In the comparative example, the specific resistance becomes high as the deposition temperature is lowered, and when the deposition temperature is 300° C., the specific resistance becomes relatively high about 1900 μΩ·cm.

On the other hand, according to the example 1, when the deposition temperature is 300° C., for all of the samples, the specific resistances of the TiN films become lower than that of the comparative example.

Further, the sheet resistance for the case where the cycle number is 10 becomes lower than that for the case where the cycle number is 4. This result is further examined in the following example 2.

Further, as shown in FIG. 7, when the rotational speed of the turntable 2 is 30 rpm, the specific resistance of the TiN film becomes lower than that for the case when the rotational speed of the turntable 2 is 240 rpm. This means that the TiN film is more improved by the NH₃ gas as the effective period for the TiN film to be exposed to the NH₃ gas becomes longer when the rotational speed becomes lowered.

### Example 2

Next, relationships between the sheet resistance of the deposited TiN film and the period in which the TiCl₄ gas and the NH₃ gas are supplied while rotating the turntable 2, and the period in which the NH₃ gas is supplied while rotating the turntable 2 are examined.

The main conditions for the example are as follows.
the temperature of the turntable 2 (deposition temperature): 400° C.
the rotational speed of the turntable 2: 240 rpm
TiCl₄ gas flow rate: 150 sccm
NH₃ gas flow rate: 15000 sccm
the total separation gas flow rate from the separation gas nozzles 41 and 42: 10000 sccm
the targeted thickness of the TiN film: 10 nm

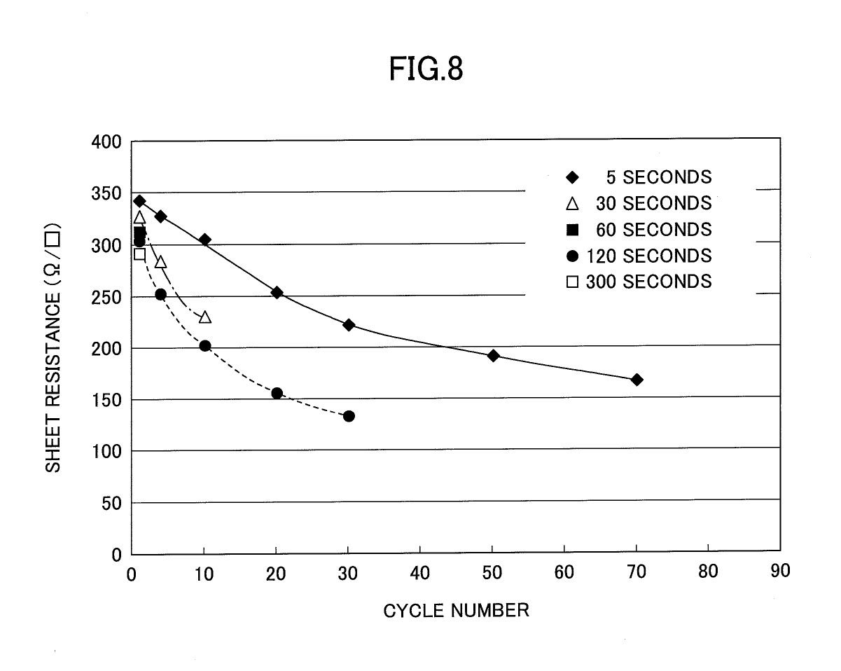

FIG. 8 is a graph showing a result of the example 2. In FIG. 8, the axis of ordinates expresses the sheet resistance, and the axis of abscissas expresses the cycle number. Further, in FIG. 8, the results in which the period of the NH₃ process step is varied for 5 seconds, 30 seconds, 60 seconds, 120 seconds, and 300 seconds are also shown.

With reference to FIG. 8, the sheet resistance becomes lower as the cycle number increases. As described above, as the cycle number is large, the film deposition step for each of the cycles becomes short so that the thickness of the TiN film deposited in the film deposition step in one cycle becomes thinner. In other words, as the cycle number increases, the thinner TiN film is exposed to the NH₃ gas in the NH₃ process step. Thus, the film quality of the TiN film is more improved by the NH₃ gas to lower the sheet resistance.

Further, as shown in FIG. 8, as the period of the NH₃ process step becomes longer, the sheet resistance is lowered. This means that at this time, the TiN film is exposed to the NH₃ gas for longer periods so that the film quality of the TiN film is more improved. Especially, when the period of the NH₃ process step is 120 seconds, the sheet resistance is 250 Ω/sq., which is low enough in practical use, even when the cycle number is about 4.

### Example 3

Then, the rotational speed of the turntable 2 is further varied and a relationship between the sheet resistance of the TiN film and the cycle number is examined.

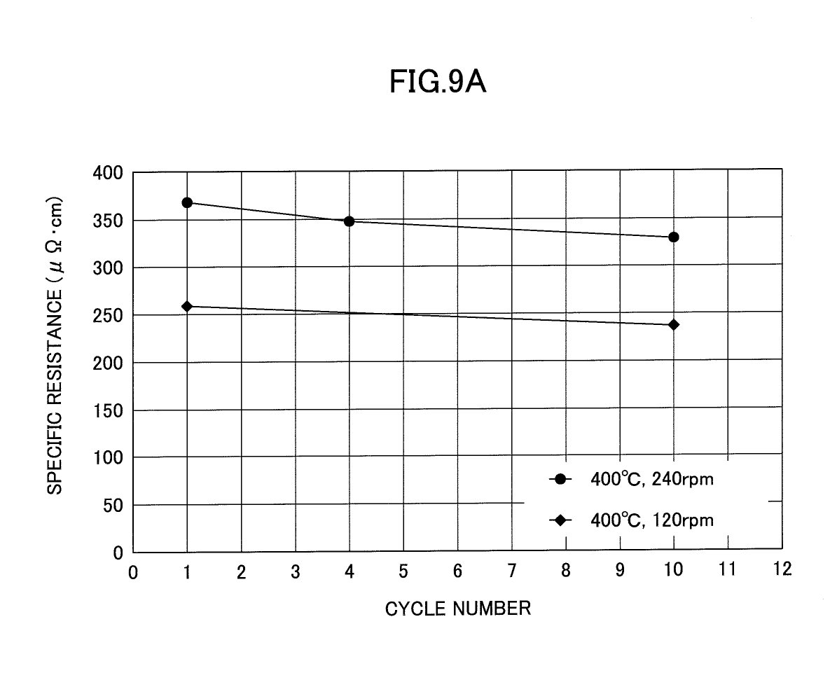

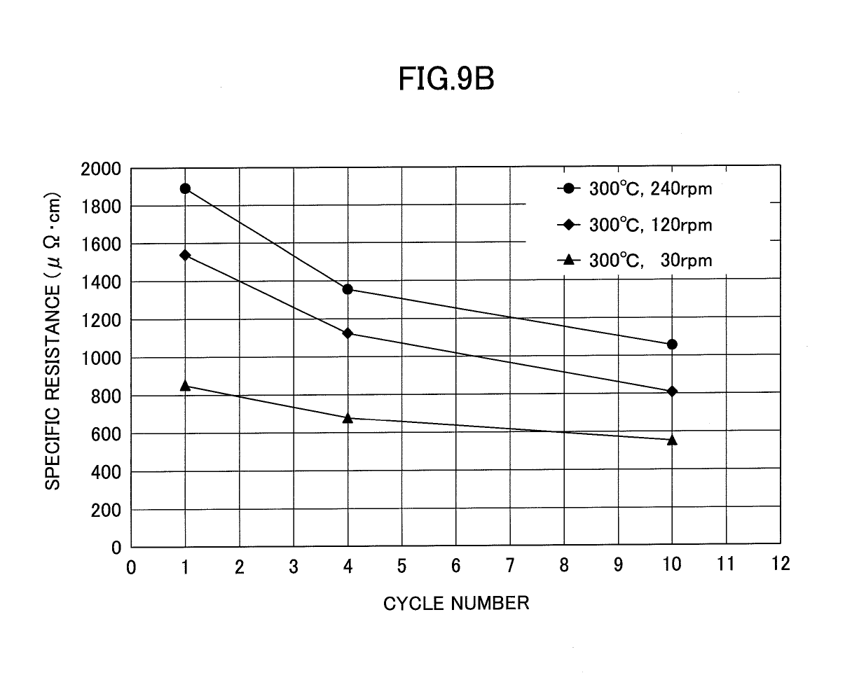

FIG. 9A is a graph showing a relationship between the specific resistance of the TiN film and the cycle number when the deposition temperature is 400° C. and the rotational speed of the turntable 2 is 120 rpm or 240 rpm. At this time, when the cycle number is increased from 1 to 10, the specific resistance is lowered. Further, when the rotational speed of the turntable 2 is lowered from 240 rpm to 120 rpm, the specific resistance is greatly decreased.

FIG. 9B is a graph showing a relationship between the sheet resistance of the TiN film and the cycle number when the deposition temperature is 300° C. and the rotational speed of the turntable 2 is 30 rpm, 120 rpm, or 240 rpm. Compared with the case when the deposition temperature is 400° C., the specific resistance is greatly lowered when the cycle number is increased in the case where the deposition temperature is 300° C. Further, for the case when the deposition temperature is 300° C., when the rotational speed of the turntable 2 is lowered, the specific resistance of the TiN film is also lowered.

As described above, according to the film deposition method of the embodiment, the film deposition step in which the TiN film is deposited on the wafer W by supplying the TiCl₄ gas and the NH₃ gas while rotating the turntable 2 on which the wafer W is mounted, and the NH₃ process step in which the TiN film on the wafer W is exposed to the NH₃ gas by supplying the NH₃ gas while rotating the turntable 2 are repeatedly performed. The film quality of the TiN film is improved by exposing the TiN film to the NH₃ gas as the unreacted TiCl₄ remaining in the TiN film reacts with the NH₃ gas, or Cl generated by the decomposition of TiCl₄ and remaining in the TiN film reacts with NH₃ gas to be eliminated from the TiN film as NH₄Cl. Thus, the sheet resistance of the TiN film can be lowered. Especially, by increasing the cycle number of the film deposition step and the NH₃ process step, the film quality of the TiN film can be effectively improved as the relatively thin TiN film can be exposed to the NH₃ gas.

Here, for example, when performing the NH₃ process in which only the NH₃ gas is supplied after depositing the TiN film in a batch CVD apparatus or a single wafer processing type CVD apparatus, it is necessary to sufficiently purge the NH₃ gas in a chamber. This is because the quality of the TiN film is greatly influenced by the flow rate ratio of the TiCl₄ gas and the NH₃ gas when depositing the TiN film. It means that if the NH₃ gas used in the NH₃ process remains in the chamber, the desired flow rate ratio cannot be actualized. Thus, there is a problem in that a step of purging the NH₃ gas is necessary to increase the period for the process. Further, if the deposition period for each of the cycles is made short, the number of times for the purging step is increased to further increase the process period.

On the other hand, according to the film deposition method of the embodiment, as the NH₃ gas is supplied from the reaction gas nozzle 32 which is apart from the reaction gas nozzle 31 which supplies the TiCl₄ gas in the rotation direction of the turntable 2, the wafer W is exposed to the TiCl₄ gas in an atmosphere where the NH₃ gas does not exist. Further, in the film deposition apparatus as explained above which may be preferably used for performing the film deposition method of the embodiment, the protruding portions 4 which provide the low ceiling surfaces 44 with respect to the turntable 2 are provided between the reaction gas nozzle 31 and the reaction gas nozzle 32, and further the separation gas flows through the spaces between the turntable 2 and the low ceiling surfaces 44, respectively, so that the TiCl₄ gas and the NH₃ gas can be separated. Thus, the film deposition step (S63) can be performed after the NH₃ process step (S65) without purging the NH₃ gas. In other words, it is unnecessary to perform the NH₃ gas purging step which is normally used to prevent the process period from increasing.

Further, the NH₃ gas purging step is necessary in a batch ALD apparatus. Further, even the film deposition method of the embodiment may be performed in the batch ALD apparatus, if the period for each of the film deposition steps is made short, and the number of times of purging the TiCl₄ gas when performing the film deposition or the number of times of purging the NH₃ gas are increased to cause a longer process period.

As described above, according to the film deposition method, the sheet resistance of the TiN film can be lowered even at a low deposition temperature about 300° C., and the process period can be prevented from being increased.

The present invention is not limited to the specifically disclosed embodiments, and variations and modifications may be made without departing from the scope of the present invention.

For example, as shown in FIG. 2 and FIG. 3, a reaction gas nozzle 92, having the same structure as the reaction gas nozzle 32 which supplies the NH₃ gas, may be provided downstream in the rotation direction of the turntable 2 with respect to the reaction gas nozzle 32 and the NH₃ gas may be supplied from the reaction gas nozzle 92. With this, the wafer W can be exposed to the NH₃ gas with a higher concentration so that the film quality of the deposited TiN film can be improved (the resistance is lowered). Supplying of the NH₃ gas from the reaction gas nozzle 92 may be performed only when the TiCl₄ gas is not supplied from the reaction gas nozzle 31 or may be performed when the TiCl₄ gas is being supplied. Further, the flow rate of the NH₃ gas from the reaction gas nozzle 32 and the flow rate of the NH₃ gas from the reaction gas nozzle 92 may be the same, or the flow rate of the NH₃ gas from the reaction gas nozzle 92 may be set higher than that from the reaction gas nozzle 32.

Here, the reaction gas nozzle 92 shown in FIG. 2 and FIG. 3 extends in a substantially parallel relationship with respect to the surface of the turntable 2 in a radial direction of the vacuum chamber 10 by fixing an introduction port 92a to the side wall of the chamber body 12, similar to the reaction gas nozzles 31 and 32.

The gas (titanium containing gas) supplied from the reaction gas nozzle 31 is not limited to the TiCl₄ gas and an organic source containing titanium may be used, for example. Further, the gas (nitrogen containing gas) supplied from the reaction gas nozzle 32 is not limited to the ammonia gas and a Monomethylhydrazine may be used, for example.

Further, in the above embodiment, as explained above with reference to FIG. 11, the TiN film with a desired thickness “d” is deposited by repeatedly depositing the TiN film with the thickness “d/n” in the film deposition step 200, and film deposition step 200 and the NH₃ process step 202 are repeated for “n” times. However, alternatively, the thickness of the TiN film deposited in each cycle of the film deposition step 200 may not be the same. For example, as the NH₃ process step 202 is performed for many times for the TiN film formed earlier, there is a possibility that the annealing effect of the NH₃ process step 202 is increased. Thus, for example, the thickness of the TiN film may be greater for the earlier deposited TiN film and the thickness of the TiN film may be made less as the process proceeds. Anyway, the thickness of the TiN film deposited in each of the cycles may be appropriately controlled so that the finally obtained TiN film has the desired thickness.

According to the embodiment, a film deposition method capable of reducing the resistance of TiN is provided.

Although a preferred embodiment of the film deposition method has been specifically illustrated and described, it is to be understood that minor modifications may be made therein without departing from the sprit and scope of the invention as defined by the claims.

What is claimed is:

1. A film deposition method, comprising:
a film depositing step of depositing titanium nitride on a substrate mounted on a substrate mounting portion of a turntable, which is rotatably provided in a vacuum chamber, by alternately exposing the substrate to a titanium containing gas and a nitrogen containing gas which is capable of reacting with the titanium containing gas while rotating the turntable; and
an exposing step of exposing the substrate on which the titanium nitride is deposited to the nitrogen containing gas,
the film depositing step and the exposing step being continuously repeated to deposit the titanium nitride of a desired thickness.

2. The film deposition method according to claim 1,
wherein in the film deposition step, the substrate is exposed to an inert gas between being exposed to the titanium containing gas and the nitrogen containing gas.

3. The film deposition method according to claim 1,
wherein in the exposing step, the substrate is exposed to the nitrogen containing gas and an inert gas in this order.

4. The film deposition method according to claim 1,
wherein the titanium containing gas is supplied from a first reaction gas supplying portion toward the turntable, and
the nitrogen containing gas is supplied from a second reaction gas supplying portion, which is provided to be apart from the first reaction gas supplying portion in the rotation direction of the turntable, toward the turntable.

5. The film deposition method according to claim 2,
wherein the titanium containing gas is supplied from a first reaction gas supplying portion toward the turntable,
the nitrogen containing gas is supplied from a second reaction gas supplying portion, which is provided to be apart from the first reaction gas supplying portion in the rotation direction of the turntable, toward the turntable, and
the inert gas is supplied from a space between a low ceiling surface and the turntable between the first reaction gas supplying portion and the second reaction gas supplying portion in the rotation direction of the turntable, the low ceiling surface being lower than ceiling surfaces at areas where the first reaction gas supplying portion and the second reaction gas supplying portion are respectively provided.

6. The film deposition method according to claim 1,
wherein the titanium containing gas is a titanium chloride gas and the nitrogen containing gas is an ammonia gas.

7. The film deposition method according to claim 1,
wherein the film deposition step and the subsequent exposing step are repeated for plural times and the titanium nitride of a thickness less than the desired thickness is formed in each of the film deposition steps.

8. The film deposition method according to claim 7,
wherein the film deposition step and the subsequent exposing step are repeated “n” times and the titanium nitride of a thickness of “d/n” is formed in each of the film deposition steps when the desired thickness is “d”.

9. The film deposition method according to claim 4,
wherein in the film deposition step, the titanium containing gas is supplied from the first reaction gas supplying portion toward the turntable while the nitrogen containing gas is supplied from the second reaction gas supplying portion toward the turntable, and
in the exposing step, the titanium containing gas is not supplied from the first reaction gas supplying portion, and the nitrogen containing gas is supplied from the second reaction gas supplying portion toward the turntable.
